(19) United States
(12) Patent Application Publication
(10) Pub. No.: US 2021/0355571 A1
(43) Pub. Date: Nov. 18, 2021

(54) MASK AND MASK CLEANING METHOD

(71) Applicant: Wuhan China Star Optoelectronics Semiconductor Display Technology Co., Ltd., Wuhan (CN)

(72) Inventor: Ketao NING, Wuhan (CN)

(21) Appl. No.: 16/323,517

(22) PCT Filed: Oct. 12, 2018
(86) PCT No.: PCT/CN2018/110019

§ 371 Date: Feb. 5, 2019

(30) Foreign Application Priority Data
Sep. 18, 2018 (CN) 20181100190035.3

(51) Int. Cl. C23C 14/04; C23C 14/12; H01L 51/00

(52) U.S. Cl. CPC C23C 14/042; H01L 51/0011; C23C 14/12

(57) ABSTRACT

The present disclosure provides a mask and a mask cleaning method, wherein the mask comprises a substrate layer, a spray layer and a disassembly member; wherein the spray layer is configured to adsorb particles generated during the physical vapor deposition performed on the display device by adopting the mask; wherein the disassembly member is configured to fix the spray layer on the substrate layer during the physical vapor deposition performed on the display device by the mask, and is configured to strip the spray layer from the substrate layer.

### FIELD OF INVENTION

The present disclosure relates to the field of display technology, and more particularly to a mask and a mask cleaning method.

### BACKGROUND OF INVENTION

Organic light-emitting diodes (OLEDs) having advantages of a quick response, a wide viewing angle, and flexible display dominate in the display field.

A physical vapor deposition is performed on the OLEDs by a mask to generate a light-emitting layer during an OLED process. The mask includes a substrate layer and a spray layer formed by using sand blasting on the substrate layer. The spray layer is configured to absorb particles. More and more particles are absorbed on a surface of the spray layer with a long term use of the mask. Therefore, the mask is needed to be cleaned at a regular interval. However, acidity liquids are generally used to clean the mask and may result in damages of the mask.

### SUMMARY OF INVENTION

An object of the present disclosure is to provide a mask and a mask cleaning method to decrease a damage rate of the mask.

The present disclosure provides a mask, utilized for physical vapor deposition on a display device, including: a substrate layer, a spray layer and a disassembly member.

The spray layer is configured to adsorb particles generated during the physical vapor deposition performed on the display device by adopting the mask.

The disassembly member is configured to fix the spray layer on the substrate layer during the physical vapor deposition performed on the display device by the mask, and is configured to strip the spray layer from the substrate layer.

The disassembly member includes a stickup layer disposed between the substrate layer and the spray layer.

The disassembly member includes a groove and a bump matched with the groove.

The groove is disposed at a side of the substrate layer opposite to the spray layer and the bump is disposed at a side of the spray layer opposite to the substrate layer; or the groove is disposed at a side of the spray layer opposite to the substrate layer and the bump is disposed at a side of the substrate layer opposite to the spray layer.

According to some embodiments, the spray layer is formed by sand blasting the stickup layer.

According to some embodiments, a thickness of the stickup layer ranges from 50 um to 90 um.

According to some embodiments, constituent materials of the stickup layer is at least one selected from the group consisting of polyimides and acrylics.

According to some embodiments, the disassembly member includes a screw, a thread groove and a threaded hole, and both the thread groove and the threaded hole matched with the screw.

The threaded hole is disposed in the substrate layer, and the thread groove is disposed at a side of the spray layer opposite to the substrate layer.

The threaded hole is disposed in the spray layer, and the thread groove is disposed at a side of the substrate layer opposite to the spray layer.

According to some embodiments, the spray layer includes a substrate and an absorption layer disposed on the substrate.

The absorption layer is formed by utilizing sand blasting on the substrate.

According to some embodiments, constituent materials of the substrate is at least one or more than one selected from the group consisting of titanium, aluminum and chromium.

The present disclosure provides a mask, utilized for physical vapor deposition on a display device, including: a substrate layer, a spray layer and a disassembly member.

The spray layer is configured to adsorb particles generated during the physical vapor deposition performed on the display device by adopting the mask.

The disassembly member is configured to fix the spray layer on the substrate layer during the physical vapor deposition performed on the display device by the mask, and is configured to strip the spray layer from the substrate layer.

According to some embodiments, the disassembly member includes a stickup layer.

The stickup layer is disposed between the substrate layer and the spray layer.

According to some embodiments, the spray layer is formed by sand blasting the stickup layer.

According to some embodiments, a thickness of the stickup layer ranges from 50 um to 90 um.

According to some embodiments, constituent materials of the stickup layer is at least one selected from the group consisting of polyimides and acrylics.

According to some embodiments, the disassembly member includes a groove and a bump matched with the groove.

The groove is disposed at a side of the substrate layer opposite to the spray layer and the bump is disposed at a side of the spray layer opposite to the substrate layer; or the groove is disposed at a side of the spray layer opposite to the substrate layer and the bump is disposed at a side of the substrate layer opposite to the spray layer.

According to some embodiments, the disassembly member includes a screw, a thread groove and a threaded hole, and both the thread groove and the threaded hole matched with the screw.

The threaded hole is disposed in the substrate layer, and the thread groove is disposed at a side of the spray layer opposite to the substrate layer.

The threaded hole is disposed in the spray layer, and the thread groove is disposed at a side of the substrate layer opposite to the spray layer.

According to some embodiments, the spray layer includes a substrate and an absorption layer disposed on the substrate.

The absorption layer is formed by utilizing sand blasting on the substrate.

According to some embodiments, constituent materials of the substrate is at least one or more than one selected from the group consisting of titanium, aluminum and chromium.

The present disclosure also provides a mask cleaning method, utilized for cleaning the mask as claimed in the claim 9, including: stripping the spray layer from the substrate layer to obtain a stripped spray layer by the disassembly member; cleaning the stripped spray layer to obtain a cleaned spray layer; fixing the cleaned spray layer on the substrate layer by the disassembly member.

According to some embodiments, after cleaning the stripped spray layer to obtain a cleaned spray layer, further including: sand-blasting the cleaned spray layer.

The present disclosure provides a mask, wherein the disassembly member is disposed to disassemble the spray layer from the substrate layer, and the spray layer is cleaned alone to decrease the damage rate of the mask.

Aforementioned contents of the present disclosure will be better understood with reference to the following description, appended claims and accompanying figures.

### DESCRIPTION OF DRAWINGS

FIG. 1 is a first structural schematic diagram of a mask according to the present invention.

FIG. 2 is a second structural schematic diagram of a mask according to the present invention.

FIG. 3 is a third structural schematic diagram of a mask according to the present invention.

FIG. 4 is a flowchart schematic diagram of a mask cleaning method according to the present invention.

### DETAILED DESCRIPTION OF PREFERRED EMBODIMENTS

The following description of every embodiment with reference to the accompanying drawings is used to exemplify a specific embodiment which may be carried out in the present disclosure. Directional terms mentioned in the present disclosure, such as “top”, “bottom”, “front”, “back”, “left”, “right”, “inside”, “outside”, “side” etc., are only used with reference to the orientation of the accompanying drawings. Therefore, the used directional terms are intended to illustrate, but not to limit, the present disclosure. Examples of the described embodiments are given in the accompanying drawings, wherein the identical or similar reference numerals constantly denote the identical or similar elements or elements having the identical or similar functions.

Reference throughout the specification to “embodiment” means that a particular feature, structure, or characteristic described in connection with the embodiment is included in at least one embodiment. Thus, appearances of the phrases “embodiment” in places throughout the specification are may be combined in any suitable manner in one or more embodiments. Thus, the particular features, structures, or characteristics illustrated or described in connection with one embodiment may be combined, in whole or in part, with the features structures, or characteristics of one or more other embodiments without limitation. Such modifications and variations are intended to be included within the scope of the present invention.

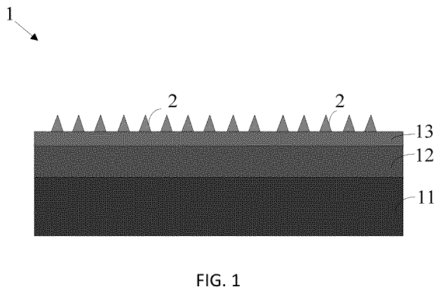

The present disclosure provides a mask. As shown in FIG. 1, the FIG. 1 is a structural schematic diagram of the mask according to the present disclosure. As shown in FIG. 1, the mask 1 includes a substrate layer 11, a spray layer 12 and a disassembly member 13. Wherein the mask 1 is configured for physical vapor deposition on a display device. The display device can be a crystal liquid display device, an organic light-emitting display device, a cathode-ray tube display device and so on, and specifically types of the display device are not limited here. The physical vapor deposition is a common technique for producing hard thin-film and includes a vacuum evaporation film technique, a vacuum sputtering coating technique, an ion plating technique and so on, and specifically types of the physical vapor deposition are not limited here.

The substrate layer 11 can be made of heat-resistance materials at least one or more than one selected from the group consisting of titanium, aluminum, chromium and so on.

As shown in FIG. 1, the disassembly member 13 is configured to fix the substrate layer 11 on the spray layer 12 when the physical vapor deposition is performed on the display device by the mask 1. So, particles 2 absorbed on the spray layer 12 cannot fall to affect a quality of the display device.

The disassembly member 13 is also configured to strip the spray layer 12 from the substrate layer 11 when cleaning the particles 2. This can only clean a stripped spray layer 12, and acidic liquids utilized for cleaning cannot damage the substrate layer 11 of the mask 1 and can reduce a damage rate of the mask 1.

A cleaned spray layer 12 is fixed on the substrate layer 11 by the disassembly member 13 after the stripped spray layer 12 being cleaned. According to an embodiment of the present disclosure, after cleaning the stripped spray layer 12, the cleaned spray layer 12 is sand-blasted to make the cleaned spray layer 12 still have a larger roughness to absorb the particles 2.

According to some embodiments, as shown in FIG. 1, the disassembly member 13 includes a stickup layer 131. Specifically, the stickup layer 131 is disposed between the substrate layer 11 and the spray layer 12 to fix the spray layer 12 on the substrate 11. When the spray layer 12 absorbs too many particles, the stickup layer 131 can be stripped from the substrate layer 11, that is, the substrate layer 11 is stripped from both the spray layer 12 and the stickup layer 131. And then, the stripped spray layer 12 is cleaned alone by the acidic liquids to avoid an erosion of the substrate layer 11 by the acidic liquids. At last, the cleaned spray layer 12 is continue to be fixed on the substrate layer 11 by the stickup layer 131.

Constituent materials of the stickup layer 131 includes some materials of high heat-resistance and high adhesive force. According to an embodiment, the constituent materials of the stickup layer 131 can be at least one selected from the group consisting of polyimides and acrylics. According to an embodiment, a thickness of the stickup layer 131 can range from 50 um to 90 um.

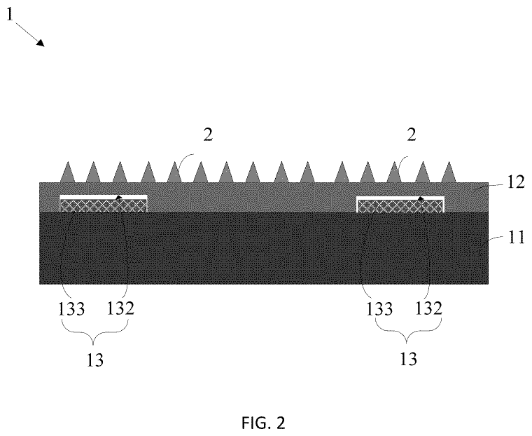

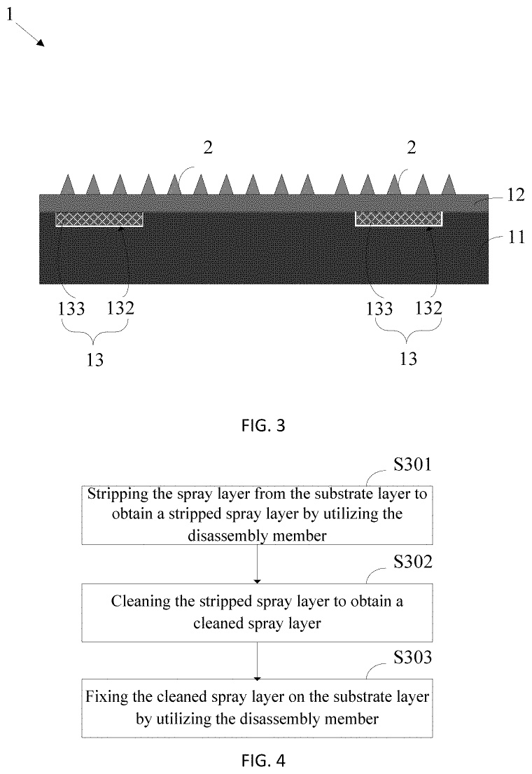

According to some embodiments, as shown in FIG. 1 or FIG. 2, the disassembly layer 13 includes a groove 132 and a bump 133 matched with the groove 132. As shown in FIG. 2, the groove 132 can be disposed at a side of the substrate layer 11 opposite to the spray layer 12 and the bump 133 can be disposed at a side of the spray layer 12 opposite to the substrate layer 11. As shown in FIG. 3, the groove 132 can be disposed at a side of the spray layer 12 opposite to the substrate layer 11 and the bump 133 can be disposed at a side of the substrate layer 11 opposite to the spray layer 12.

The bump 133 can be inserted into the groove 132 to fix the spray layer 12 on the substrate layer 11 when the physic vapor deposition is performed on the display device by the mask 1, regardless of whether the groove 132 and the bump 133 is disposed as shown in FIG. 2 or FIG. 3. When cleaning the particles 2 on the spray layer 12, the bump 133 is taken out from the groove 132 at first. And then, the stripped spray layer 12 is cleaned alone by acidic liquids to avoid an erosion of the substrate layer 11 by the acidic liquids.

According to some embodiments, the disassembly member 13 also includes a screw, a thread groove and a threaded hole, and both the thread groove and the threaded hole matched with the screw. The threaded hole can be disposed in the substrate layer 11, and the thread groove is disposed at a side of the spray layer 12 opposite to the substrate layer 11. The threaded hole can be disposed in the spray layer 12, and the thread groove is disposed at a side of the substrate layer 11 opposite to the spray layer 12. Above all, the screw is passed through the threaded hole and is inserted into the thread groove to fix the spray layer 12 on the substrate layer 11 when a physical vapor deposition is performed on the display device by the mask 1. When cleaning the particles 2 on the spray layer 12, the screw is taken out of the threaded hole to strip the spray layer 12 from the substrate layer 11, and then, cleaning the stripped spray layer 12 alone by the acidic liquids to avoid the erosion of the substrate layer 11 by the acidic liquids.

The spray layer 12 is configured to absorb the particles 2. The particles 2 are generated when the physical vapor deposition is performed on the display device by the mask 1. When the disassembly member 13 includes a stickup layer 131, the stickup layer 131 can be sand-blasted to form the spray layer 12 with a larger roughness.

When the disassembly member 13 includes a groove 132 and a bump 133 matched with the groove 132, or when the disassembly member 13 includes a screw, a thread groove and a threaded hole wherein both the thread groove and the threaded hole matched with the screw, the spray layer 12 can be made of materials of high heat-resistance and high adhesive force. According to some embodiments, the spray layer 12 also includes a substrate and an absorption layer disposed on the substrate. Wherein the absorption layer is formed by utilizing sand blasting on the substrate. Specifically, constituent materials of the substrate is at least one or more than one selected from the group consisting of titanium, aluminum and chromium.

The present disclosure provides a mask, wherein the disassembly member is disposed to disassemble the spray layer from the substrate layer, and the spray layer is cleaned alone to decrease the damage rate of the mask.

The present disclosure provides a mask cleaning method. As shown in FIG. 3, FIG. 3 is a flowchart schematic diagram of the mask cleaning method according to the present disclosure. As shown in FIG. 3, concrete steps of the mask cleaning method includes:

S101, Stripping the spray layer from the substrate layer to obtain a stripped spray layer by utilizing the disassembly member.

According to some embodiments, as shown in FIG. 1, the disassembly member 13 includes a stickup layer 131. The stickup layer 131 can be stripped directly from the substrate layer 11 to strip the spray layer 12 from the substrate layer 11.

According to some embodiments, as shown in FIG. 1 or FIG. 2, the disassembly layer 13 includes a groove 132 and a bump 133 matched with the groove 132. The bump 133 can be taken out of the groove 132 to strip the spray layer 12 from the substrate layer 11.

According to some embodiments, the disassembly layer 13 also includes a screw, a thread groove and a threaded hole, and both the thread groove and the threaded hole matched with the screw. The screw can be taken out of the thread groove to strip the spray layer 12 from the substrate layer 11.

S102, Cleaning the stripped spray layer to obtain a cleaned spray layer.

Specifically, the particles absorbed on the spray layer 12 can be cleaned up to obtain a cleaned spray layer by adopting the acidic liquids to clean the stripped spray layer. According to some embodiments, the cleaned spray layer 12 can be sand-blasted to make the cleaned spray layer 12 have a larger roughness and to absorb the particles 2, after cleaning the stripped spray layer 12.

S103, Fixing the cleaned spray layer on the substrate layer by utilizing the disassembly member.

As shown in FIG. 1, when the disassembly member 13 includes a stickup layer 131, the cleaned spray layer 12 is continue to be fixed on the substrate layer 11 by the stickup layer 131.

As shown in FIG. 2 or FIG. 3, the disassembly layer 13 includes a groove 132 and a bump 133 matched with the groove 132. The bump 133 can be inserted into the groove 132 to fix the spray layer 12 on the substrate layer 11.

The disassembly layer 13 includes a screw, a thread groove and a threaded hole, and both the thread groove and the threaded hole matched with the screw. The screw can be passed through the threaded hole and can be inserted into the thread groove to fix the spray layer 12 on the substrate layer 11.

The present disclosure provides a mask cleaning method, wherein the disassembly member is disposed to disassemble the spray layer from the substrate layer, and the spray layer is cleaned alone to decrease the damage rate of the mask.

The present disclosure is described in detail in accordance with the above contents with the specific preferred examples. However, this present disclosure is not limited to the specific examples. For a person of ordinary skill in the art, on the premise of keeping the conception of the present disclosure, the technical personnel can also make simple deductions or replacements, all of which should be considered to belong to the protection scope of the present disclosure.

1. A mask, utilized for physical vapor deposition on a display device, comprising: a substrate layer, a spray layer and a disassembly member;
wherein the spray layer is configured to adsorb particles generated during the physical vapor deposition performed on the display device by adopting the mask;
wherein the disassembly member is configured to fix the spray layer on the substrate layer during the physical vapor deposition performed on the display device by the mask, and is configured to strip the spray layer from the substrate layer;
wherein the disassembly member comprises a stickup layer disposed between the substrate layer and the spray layer;
wherein the disassembly member comprises a groove and a bump matched with the groove;
wherein the groove is disposed at a side of the substrate layer opposite to the spray layer and the bump is disposed at a side of the spray layer opposite to the substrate layer; or
wherein the groove is disposed at a side of the spray layer opposite to the substrate layer and the bump is disposed at a side of the substrate layer opposite to the spray layer.

2. The mask as claimed in claim 1, wherein the spray layer is formed by utilizing sand blasting on the stickup layer.

3. The mask as claimed in claim 1, wherein a thickness of the stickup layer ranges from 50 um to 90 um.

4. The mask as claimed in claim 1, wherein constituent materials of the stickup layer is at least one selected from the group consisting of polyimides and acrylics.

5. The mask as claimed in claim 1, wherein the disassembly member comprises a screw, a thread groove and a threaded hole, and both the thread groove and the threaded hole matched with the screw;
wherein the threaded hole is disposed in the substrate layer, and the thread groove is disposed at a side of the spray layer opposite to the substrate layer;
wherein the threaded hole is disposed in the spray layer, and the thread groove is disposed at a side of the substrate layer opposite to the spray layer.

6. The mask as claimed in claim 5, wherein the spray layer comprises a substrate and an absorption layer disposed on the substrate;
wherein the absorption layer is formed by utilizing sand blasting on the substrate.

7. The mask as claimed in claim 6, constituent materials of the substrate is at least one or more than one selected from the group consisting of titanium, aluminum and chromium.

8. A mask, utilized for physical vapor deposition on a display device, comprising: a substrate layer, a spray layer and a disassembly member;
wherein the spray layer is configured to adsorb particles generated during the physical vapor deposition performed on the display device by adopting the mask;
wherein the disassembly member is configured to fix the spray layer on the substrate layer during the physical vapor deposition performed on the display device by the mask, and is configured to strip the spray layer from the substrate layer.

9. The mask as claimed in claim 8, wherein the disassembly member comprises a stickup layer;
wherein the stickup layer is disposed between the substrate layer and the spray layer.

10. The mask as claimed in claim 9, wherein the spray layer is formed by utilizing sand blasting on the stickup layer.

11. The mask as claimed in claim 9, wherein a thickness of the stickup layer ranges from 50 um to 90 um.

12. The mask as claimed in claim 9, wherein constituent materials of the stickup layer is at least one selected from the group consisting of polyimides and acrylics.

13. The mask as claimed in claim 8, wherein the disassembly member comprises a groove and a bump matched with the groove;
wherein the groove is disposed at a side of the substrate layer opposite to the spray layer and the bump is disposed at a side of the spray layer opposite to the substrate layer; or
wherein the groove is disposed at a side of the spray layer opposite to the substrate layer and the bump is disposed at a side of the substrate layer opposite to the spray layer.

14. The mask as claimed in claim 8, wherein the disassembly member comprises a screw, a thread groove and a threaded hole, and both the thread groove and the threaded hole matched with the screw;
wherein the threaded hole is disposed in the substrate layer, and the thread groove is disposed at a side of the spray layer opposite to the substrate layer;
wherein the threaded hole is disposed in the spray layer, and the thread groove is disposed at a side of the substrate layer opposite to the spray layer.

15. The mask as claimed in claim 14, wherein the spray layer comprises a substrate and an absorption layer disposed on the substrate;
wherein the absorption layer is formed by utilizing sand blasting on the substrate.

16. The mask as claimed in claim 15, constituent material of the substrate is at least one or more than one selected from the group consisting of titanium, aluminum and chromium.

17. A mask cleaning method, utilized for cleaning the mask as claimed in the claim 9, comprising:
stripping the spray layer from the substrate layer to obtain a stripped spray layer by utilizing the disassembly member;
cleaning the stripped spray layer to obtain a cleaned spray layer;
fixing the cleaned spray layer on the substrate layer by utilizing the disassembly member.

18. The mask cleaning method as claimed in the claim 17, after cleaning the stripped spray layer to obtain a cleaned spray layer, further comprises: utilizing sand blasting on the cleaned spray layer.
